(19) United States
(12) Patent Application Publication
(10) Pub. No.: US 2025/0301672 A1
(43) Pub. Date: Sep. 25, 2025

(54) INTEGRATED MAGNETIC COMPONENT IN ELECTRONIC APPARATUS

(71) Applicant: Texas Instruments Incorporated, Dallas, TX (US)

(72) Inventors: John Carlo Molina, Limay (PH); Lorraine Quijano, Angeles (PH); Jason Colte, La Trinidad (PH)

(21) Appl. No.: 18/614,651

(22) Filed: Mar. 23, 2024

(51) Int. Cl. H01L 25/00; H01L 25/07; H02M 3/00; H02M 3/155

(52) U.S. Cl. CPC H10D 1/20; H01L 25/072; H01L 25/50; H02M 3/003; H02M 3/155

(57) ABSTRACT

An apparatus includes a packaged electronic device having a first terminal, a coil having a second terminal that is spaced apart from the first terminal, and a magnetic structure that encloses portions of the packaged electronic device and the coil and exposes respective portions of the first and second terminals. A method of manufacturing an electronic apparatus includes attaching a first terminal of a packaged electronic device to a carrier, attaching a second terminal of a coil to the carrier, performing a molding process using a magnetic molding compound to form a molded magnetic structure that encloses portions of the packaged electronic device and the coil, and removing the carrier to expose portions of the first and second terminals.

### BACKGROUND

DC to DC converters and other switching power converters often include an inductor or other magnetic component along with transistors operated as switches. Conventional power converters provide transistor switches in the form of a packaged electronic device that is soldered to a circuit board and a switching node of the transistor configuration is connected to a separate inductor component that is also soldered to the circuit board. Integrating magnetic components into integrated circuits to reduce electronic system size and increase power density has been limited to low voltage applications due to mold compound and design parameters.

### SUMMARY

In one aspect, an apparatus includes a packaged electronic device having a first terminal, a coil having a second terminal that is spaced apart from the first terminal, and a magnetic structure that encloses portions of the packaged electronic device and the coil and exposes respective portions of the first and second terminals.

In another aspect, a system includes a circuit board having a conductive trace and an apparatus attached to the circuit board. The apparatus includes a packaged electronic device having a first terminal electrically connected to the conductive trace, a coil having a second terminal that is spaced apart from the first terminal and electrically connected to the conductive trace, and a magnetic structure that encloses portions of the packaged electronic device and the coil and exposes respective portions of the first and second terminals.

In a further aspect, a method includes attaching a first terminal of a packaged electronic device to a carrier, attaching a second terminal of a coil to the carrier, performing a molding process using a molding compound to form a molded structure that encloses portions of the packaged electronic device and the coil, and removing the carrier to expose portions of the first and second terminals.

### BRIEF DESCRIPTION OF THE DRAWINGS

FIG. 1 is a partial sectional side elevation view taken along line 1-1 of FIG. 1A of a power conversion system including a leadframeless electronic apparatus with a packaged electronic device and a coil in a magnetic molded structure with exposed terminals soldered to a circuit board.

FIG. 1A is a partial top plan view of the power conversion system of FIG. 1.

FIG. 1B is a partial top plan view of the power conversion system showing a portion of the conductive landing pads and trace routings of the circuit board.

FIG. 1C is a schematic diagram showing an example implementation of the power conversion system interconnections.

FIG. 2 is a flow diagram of a method of manufacturing an electronic apparatus.

FIGS. 3-7 show an example implementation of the method of FIG. 2 using a sacrificial tape carrier.

FIG. 8 shows a partial top plan view of another leadframeless electronic apparatus example with a packaged electronic device and a coil in a magnetic molded structure with exposed terminals.

FIG. 9 shows a partial top plan view of a further leadframeless electronic apparatus example with two transistor packaged electronic devices and a coil in a magnetic molded structure with exposed terminals.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic apparatus such as an integrated circuit. While such examples may be expected to provide various improvements, no particular result is a requirement of the present disclosure unless explicitly recited in a particular claim.

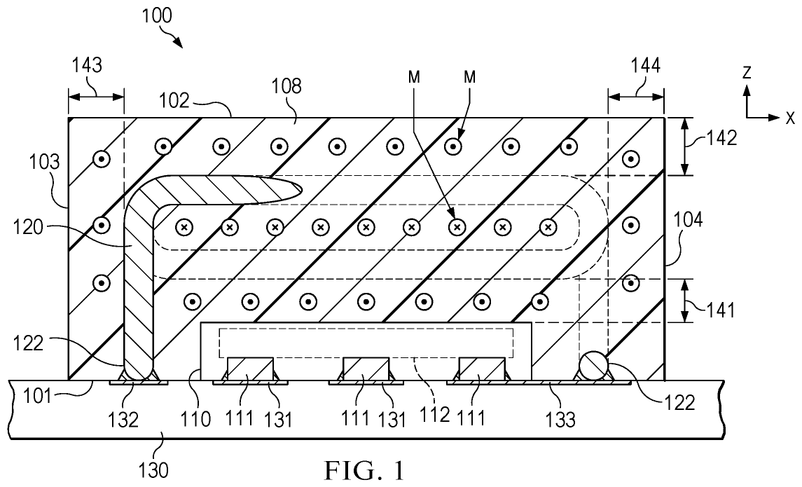

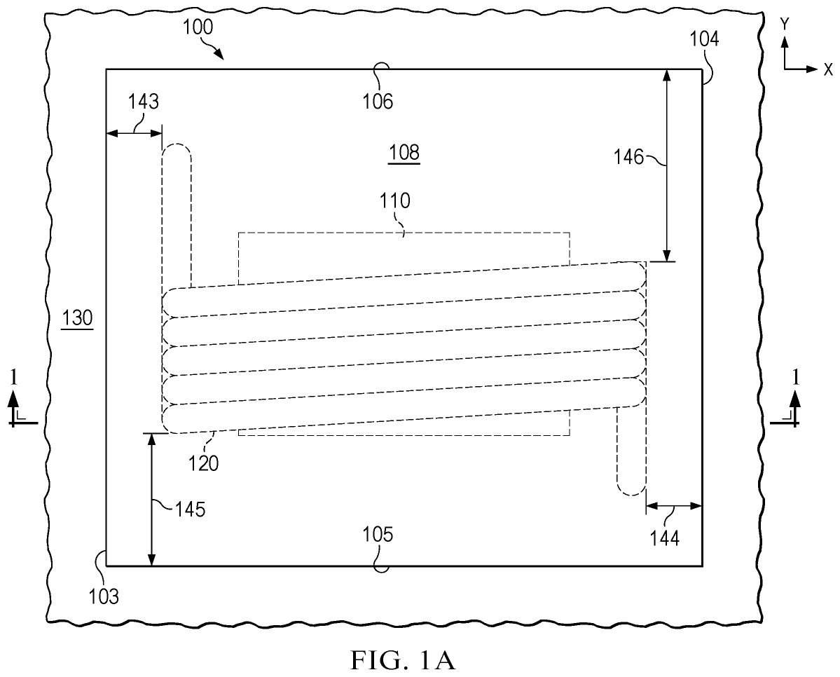

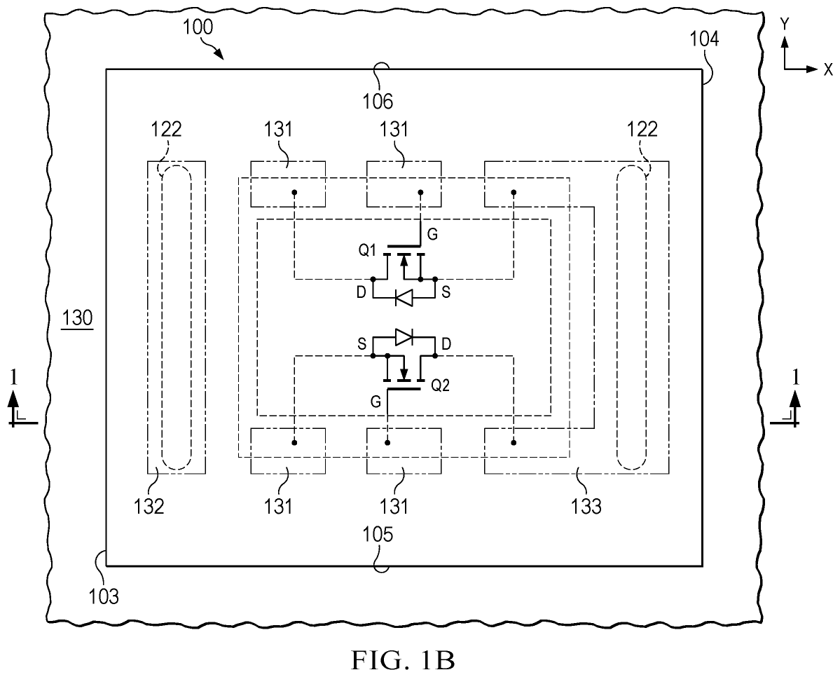

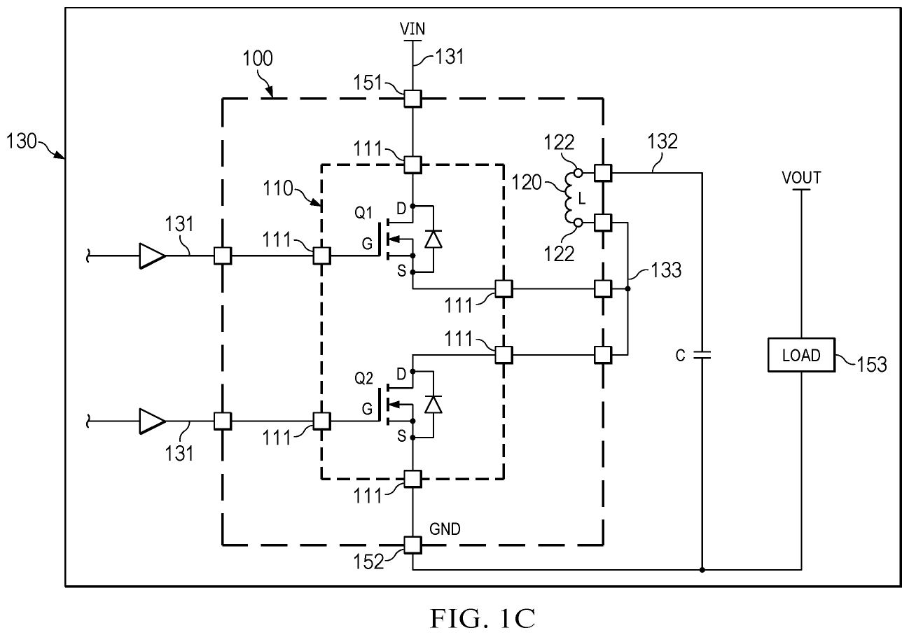

Referring initially to FIGS. 1-1C, FIG. 1 shows a sectional side view of an electronic apparatus 100 in a power conversion system taken along line 1-1 of FIG. 1A, FIG. 1A shows a partial top view of the power conversion system, FIG. 1B shows a top view of conductive landing pads and trace routings of a system circuit board, and FIG. 1C shows a schematic diagram of an example implementation of the power conversion system interconnections. FIGS. 1-1B show the apparatus 100 in an example three-dimensional space with a first direction X, a perpendicular (orthogonal) second direction Y, and a third direction Z (FIG. 1) that is perpendicular (orthogonal) to the respective first and second directions X and Y. Structures or features along any two of these directions are orthogonal to one another. As shown in FIG. 1, the electronic apparatus 100 has opposite first and second (e.g., bottom and top) sides 101 and 102, respectively, which are spaced apart from one another along the third direction Z in the illustrated position. The electronic apparatus 100 also has opposite third and fourth sides 103 and 104 (e.g., lateral sides) that are spaced apart from one another along the first direction X, and fifth and sixth sides 105 and 106 that are spaced apart from one another along the second direction Y in the illustrated position.

The apparatus 100 is a leadframeless structure having terminals of a packaged device and an integrated coil exposed along the bottom first side thereof for direct soldering to a circuit board or direct electrical connection to a corresponding socket (not shown). The leadframeless structure allows significant cost reduction in terms of materials and manufacturing complexity and facilitates high-voltage operation for power converters or other applications, particularly compared with attempts to integrate magnetic components at the die or wafer level. In addition, the described examples have reduced cost compared to integrated magnetics in packages having a lead frame and/or multilevel package substrate.

The apparatus 100 includes a molded structure 108, in one example formed of magnetic molding compound, sometimes referred to as magnetic mold compound. This limitation is referred to herein as a magnetic structure 108. Various implementations can include one or more packaged electronic devices. The illustrated example apparatus includes a packaged electronic device 110 having multiple instances of a first terminal 111. Any suitable type and form of packaged electronic device 110 can be used that includes a single electronic component (e.g., transistor, resistor, capacitor, inductor, diode, etc.) or an integrated circuit with multiple electronic components. The packaged electronic device 110 can include one or more semiconductor dies and one or more instances of the first terminal 111 to provide external conductivity to the circuit or component thereof, along with a package structure (e.g., non-magnetic plastic molded structure, ceramic structure, etc.) that at least partially encloses the semiconductor die or dies and exposes the instances of the first terminal 111. In one example, the packaged electronic device 110 has a no lead package shape, such as a dual flat no lead (DFN) or quad flat no lead (QFN) shape with instances of the first terminal 111 exposed outside the non-magnetic package structure along two or more lateral sides and a bottom side thereof. In another example, the packaged electronic device 110 has a small outline transistor (SOT) package shape. The packaged electronic device can include any suitable form of electrical interconnection of the first terminals 111 to the components or circuitry of the semiconductor die 112, such as flip chip die attachment to a lead frame, bond wires, etc.

The illustrated packaged electronic device 110 has a dual transistor packaged electronic device 110 with a semiconductor die 112 that is electrically connected to the instances of the first terminal 111. The packaged electronic device 110 has a semiconductor die 112 (FIGS. 1 and 1B), and the semiconductor die 112 includes first and second field effect transistors Q1 and Q2 as schematically illustrated in FIGS. 1B and 1C to facilitate interconnection in a half bridge transistor circuit for power switching applications. The packaged electronic device 110 has a non-magnetic structure with a DFN shape that encloses the semiconductor die 112 and exposes lower and side portions of six instances of the first terminal 111 as schematically illustrated in FIG. 1C. As shown in FIGS. 1B and 1C, the individual transistors Q1 and Q2 each have a transistor source terminal S, a transistor drain terminal D, and a transistor gate terminal G, and each of the transistor terminals S, D, and G are connected to a respective instance of the first terminal 111. The example transistors are n-channel FETs, although different types of transistors (e.g., bipolar transistors, IGBTs, etc.) and/or other electronic components can be used in different implementations. The example electronic device 110 provides a compact half bridge module that can be interconnected with the integrated coil 124 for use as a compact DC to DC converter, single phase DC to AC inverter, or the other type of power converter circuit module.

The apparatus 100 also includes an integrated magnetic component with one or more terminals exposed along the bottom or first side 101 for interconnection in a system application. The illustrated example includes an integrated coil 120 having first and second instances of a second terminal 122. The individual instances of the second terminal 122 are spaced apart from each instance of the first terminal 111. The first and second terminals 111 and 122 are partially exposed along the first side 101 to allow mechanical and electrical connection thereof to a host system, such as by soldering to a host circuit board and/or installation into a corresponding socket (not shown) of a host system. The magnetic structure 108 encloses portions of the packaged electronic device 110 and the coil 120 and exposes the respective portions of the first and second terminals 111 and 122 along the first side 101.

The illustrated power conversion system includes a circuit board 130 with conductive metal landing pads and trace routings 131, 132, and 133 as shown in FIGS. 1 and 1B and also schematically illustrated in FIG. 1C. The use of a magnetic structure 108 that encloses the coil 120 provides a magnetic field path within the apparatus 100, and the incorporation of the coil 120 or other magnetic component within the electronic apparatus 100 conserves space on the circuit board 130 that would otherwise be occupied by an external magnetic component. As shown in FIG. 1, the first and second terminals 111 and 122 of the apparatus 100 are soldered to respective conductive landing pads and associated conductive trace routings 131, 132, and 133 of the circuit board 1309 to electrically connect the respective transistor terminals of the packaged electronic device 110 and the coil 120. As schematically shown in FIGS. 1B and 1C, the DFN example packaged electronic device 110 has a corresponding instance of the first terminal 111 electrically connected to corresponding conductive landing pads 131 and 133 of the circuit board 130, with the gate (G) and drain (D) of the first transistor Q1 and the gate (G) and source(S) of the second transistor Q2 connected to respective conductive landing pads 131. As shown in FIG. 1C, the circuit board 130 in one example includes gate drivers connected to the gate terminals (G) of the respective transistors Q1 and Q2. This example also includes trace routings to connect the drain terminal (D) of the first transistor Q1 to and input voltage node 151 (labeled VIN), and to connect the source terminal(S) of the second transistor Q2 to a ground or reference node 152 (labeled GND).

In this example, the circuit board 130 includes contiguous conductive landing pads and a conductive routing trace labeled 133 that electrically connects the source(S) of the first transistor Q1 to the drain (D) of the second transistor Q2 to form a switching node of a half bridge configuration of the transistors Q1 and Q2 schematically illustrated in FIG. 1C. As further shown in FIG. 1B, the conductive landing pad/trace routing 133 is connected to a second terminal 122 of the coil 120 to interconnect the switching node of the power conversion system with the coil 120 that operates as an output inductor labeled L in the schematic illustration of FIG. 1C. In other examples, an integrated coil can be used as a primary or secondary winding of a transformer (not shown), and multiple coils or other magnetic circuit components can be integrated into the apparatus and at least partially enclosed by the magnetic structure 108. The circuit board 130 in this example includes a conductive landing pad and trace routing 132 that connects the other terminal 122 of the coil 120 to an output voltage node (labeled VOUT) in FIG. 1C and interconnects the output node with an output capacitor (labeled C in FIG. 1C) and an output load 153.

The illustrated example coil 120 has five turns that encircle an axis that lies in a plane of the first and second directions X and Y. In other examples, the coil 120 can have at least one partial turn, or a different number of turns than the illustrated example. The coil 120 is vertically spaced apart from the packaged electronic device 110 by a first spacing distance 141 along the third direction Z as shown in FIG. 1, and the coil 120 is also vertically spaced from the top second side 102 of the magnetic structure 108 by a second spacing distance 142. As shown in FIGS. 1 and 1A, moreover, the coil 120 is laterally spaced apart from the sides 103-106 by respective spacing distances 143-146. This spacing provides magnetic paths to facilitate operation of the coil 120 as a switching inductor for the illustrated power conversion system. FIG. 1 shows example magnetic field lines labeled M, with a cross representing a field line into the page (e.g., along the second direction) and a dot representing a field line out of the page. The spacing of the coil 120 from the packaged electronic device 110 and from the sides 102-106 of the magnetic structure 108 and the associated spacing distances 141-146 can be designed according to a particular magnetic component for a given application and for a particular type of magnetic material used in forming the magnetic structure 108.

As best shown in FIG. 1, the lower extent of the turns of the coil 120 is vertically spaced from the top side of the packaged electronic device 110 by the first spacing distance 141, and the uppermost extent of the coil turns is spaced from the top or second side 102 of the magnetic structure 108 by the second spacing distance 142. As shown in FIGS. 1 and 1A, outermost extent of the turns of the coil 120 are laterally spaced by the third spacing distance 143 from the third side 103 of the magnetic structure 108, and on the opposite side, are spaced from the fourth side 104 by the fourth spacing distance 144. As further shown in FIG. 1A, moreover, one end turn of the example coil 120 is spaced apart from the fifth side 105 by the fifth spacing distance 145, and the other end turn of the coil 120 is spaced apart from the sixth side 106 by the sixth spacing distance 146.

The magnetic structure 108 in one example is made of magnetic molding compound formed during manufacturing by molding, such as injection molding, compression molding, or other suitable technique. The magnetic molding compound in one example includes ferromagnetic materials such as ferrite M33 (e.g., relative permeability of approximately 750), nickel (e.g., relative permeability of approximately 600), ferrite N41 (e.g., relative permeability of approximately 2,800), high purity iron (e.g., relative permeability of approximately 5000-200,000), ferrite T38 (e.g., relative permeability of approximately 10,000), silicon GO steel (e.g., relative permeability of approximately 40,000), and supermalloy (e.g., an alloy of nickel (75%), iron (20%), and molybdenum (5%) with a relative permeability of approximately 1,000,000) or other suitable magnetic material having sufficiently high relative permeability for a given coil design and system application. In certain implementations, the magnetic structure 108 has a relative permeability that is greater than the permeability of air, for example, and is constructed from a magnetic molding compound with a relative permeability of approximately 5 or more, which is approximately five times that of air. In other examples, the magnetic molding compound has a relative permeability of approximately 10 or more, such as 10-40.

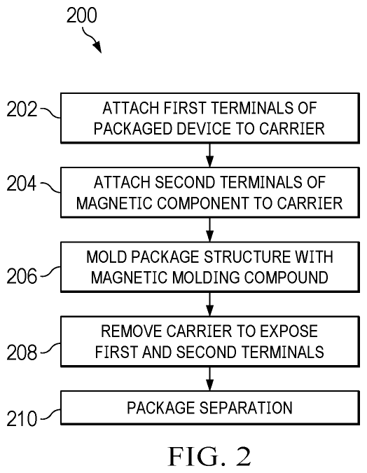

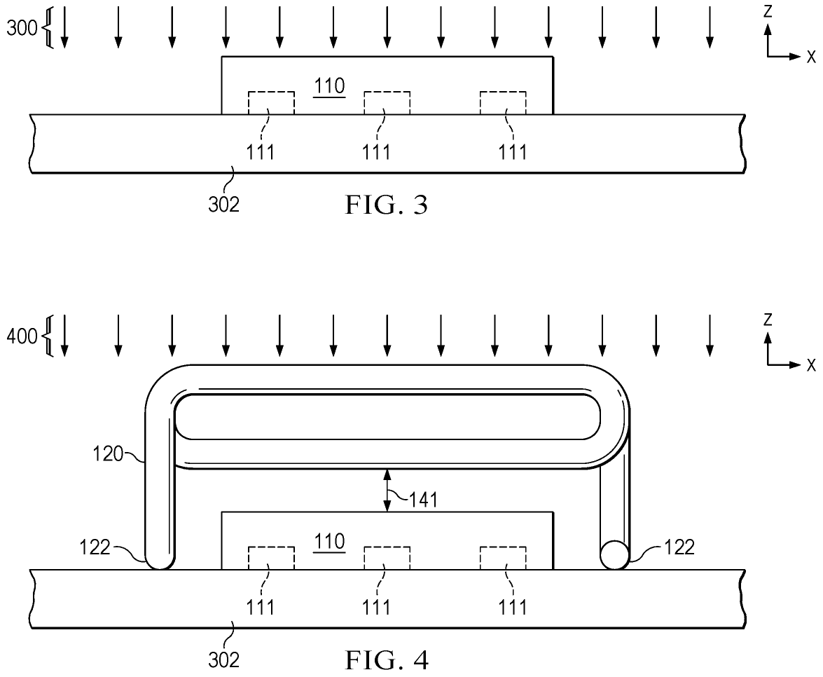

Referring also to FIGS. 2-7, FIG. 2 shows a method 200 of manufacturing an electronic apparatus and FIGS. 3-7 show an example implementation of the method 200 using a sacrificial tape carrier to fabricate an implementation of the apparatus 100 of FIGS. 1-1C. The method 200 begins at 202 in FIG. 2 with packaged electronic device attachment processing to attach the first terminals 111 of the packaged electronic device 110 to a carrier. In one example, the carrier can be a tape, such as having an adhesive on an upper side. In one implementation, the carrier is a film adhesive laminated on a metal frame or a metallic sheet. FIG. 3 shows one example, in which a tape carrier 302 is used. In another example, a lead frame, a metallic sheet (e.g., copper), or a single or multilevel package substrate (e.g., sometimes referred to as a routable lead frame) can be used as a removable carrier. In the example of FIG. 3, an attachment process 300 is performed that attaches the example 6-terminal DEN packaged electronic device 110 to the carrier 302 with the first terminals 111 of the packaged electronic device 110 engaging the adhesive top side of the carrier 302. In one implementation, the attachment processing at 202 is performed in a panel array structure having rows and columns of unit areas that individually correspond to a subsequently separated electronic apparatus 100. The attachment process 300 in FIG. 3 in one example is performed using automated pick and place equipment (not shown) that position or otherwise attached an instance of the packaged electronic device 110 in each unit area of the panel array structure.

At 204 in FIG. 2, the method 200 continues with coil attachment processing. FIG. 4 shows one example, in which an attachment process 400 is performed that attaches an instance of the coil 120 in each unit area of the panel array structure, for example, using automated pick and place equipment (not shown). The attachment process 400 in one example attaches the second terminals 122 of each coil 120 to the carrier 302 in a spaced relationship such that the coil terminals 122 and coil turns are spaced apart from the corresponding packaged electronic device 110 in each unit area of the panel array structure.

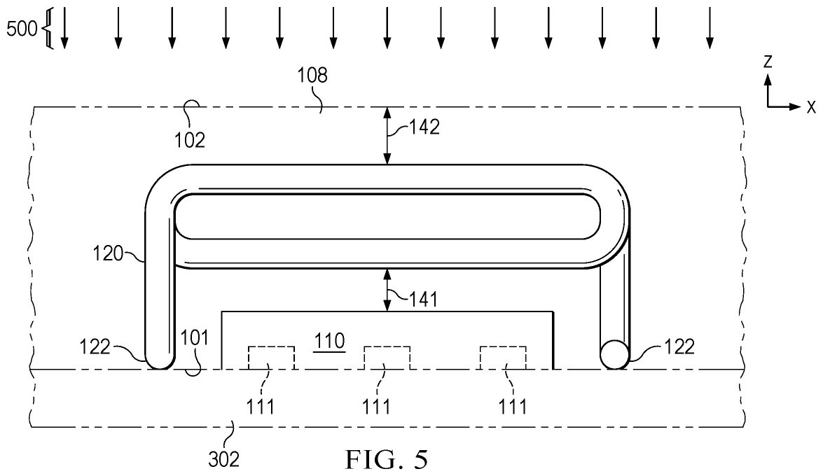

At 206 and FIG. 2, the magnetic structure 108 is formed in each unit area. FIG. 5 shows one example, in which a molding process 500 is performed that forms the molded magnetic structure 108 that encloses the upper portions of the coil 120 and the packaged electronic device 110 in each unit area of the panel array structure, with the top or second side 102 of the molded magnetic structure 108 spaced apart from and enclosing the top side of the coil 120 as shown in FIG. 5. In one implementation, the molding process 500 is a compression molding process using magnetic molding compound to provide a top or second side 102 of the compression molded structure spaced apart from the carrier 302 and from the top side of the coil 120 to provide a desired second spacing distance 142 between the top side 102 of the molded magnetic structure 108 and the coil 120. In one example, a grinding or other material removal process (e.g., laser ablation, saw cutting, etc.) can be performed after the molding operations to selectively remove material from the top side to set the final spacing distance 142 of the panel array structure. Since portions of the lower sides of the first and second terminals 111 and 122 engage the top side of the carrier 302 during the molding process 500, those portions of the terminals 111 and 122 are not enclosed or otherwise covered by the molded magnetic structure 108.

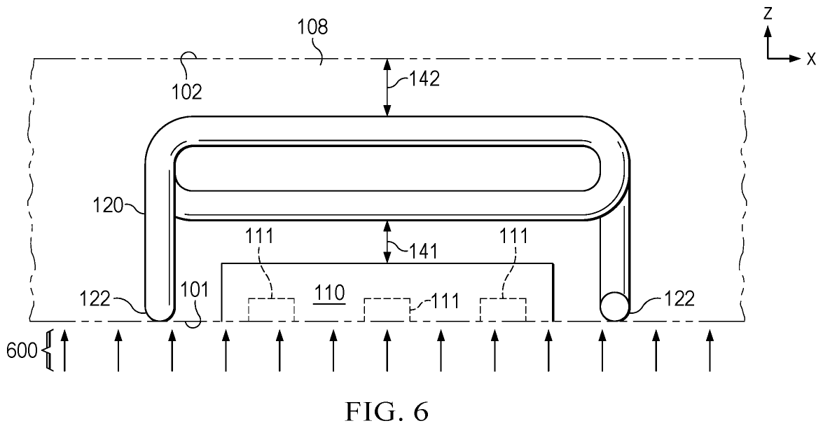

The method 200 continues at 208 in FIG. 2 with carrier removal processing. FIG. 6 shows one example, in which a carrier removal process 600 is performed that removes the carrier 302 to expose portions of the first and second terminals 111 and 122 in each unit area of the panel array structure. In one implementation using a tape carrier 302, the removal process 600 is a D tape operation that exposes the bottom sides of the first terminals 111 of the packaged electronic device 110 and exposes the bottom sides of the second terminals 122 of the coil 120 in each unit area. In another implementation using a tape carrier that is laminated to a metallic sheet, the removal process 600 at 208 can include D tape in by performing a grinding operation that grinds through the metallic sheet and the tape carrier 302. In a further implementation using a tape carrier, the removal processing at 208 can include chemical material removal steps and/or mechanical grinding or milling to expose the terminals 111 and 122 of the respective packaged electronic device 110 and the coil 120. In another example, the carrier 302 is a lead frame or a substrate, and the carrier removal process 600 (e.g., at 208 in FIG. 2) includes a grinding process that removes the lead frame or substrate carrier 302 to expose the respective portions of the first and second terminals 111 and 122.

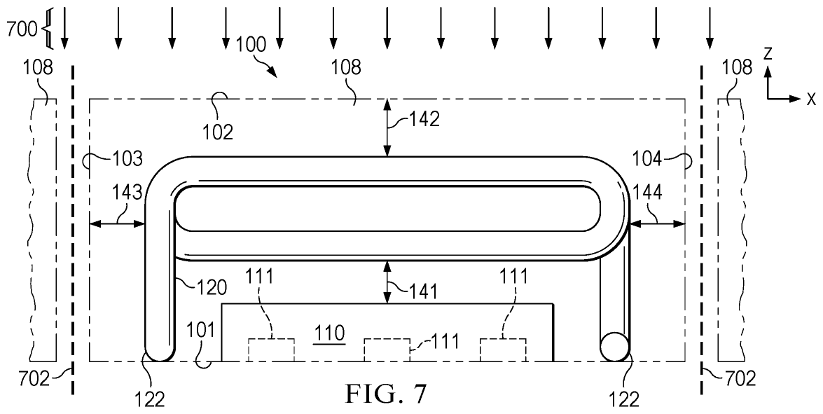

In one implementation, the carrier removal at 208 completes the apparatus assembly process 200. In the illustrated example, package separation processing can be performed at 210 in FIG. 2, for example, to separate the finished electronic apparatus 100 in each unit area from the panel array structure. FIG. 7 shows one example, in which a package separation process 700 is performed that separates individual electronic apparatus instances 100 from the panel array structure, for example, by separating the molded magnetic structure 108 along lines 702 along the row and column directions between adjacent unit areas as shown in FIG. 7. Any suitable package separation processing can be used at 210, such as laser cutting, chemical etching, mechanical sawing or combinations thereof.

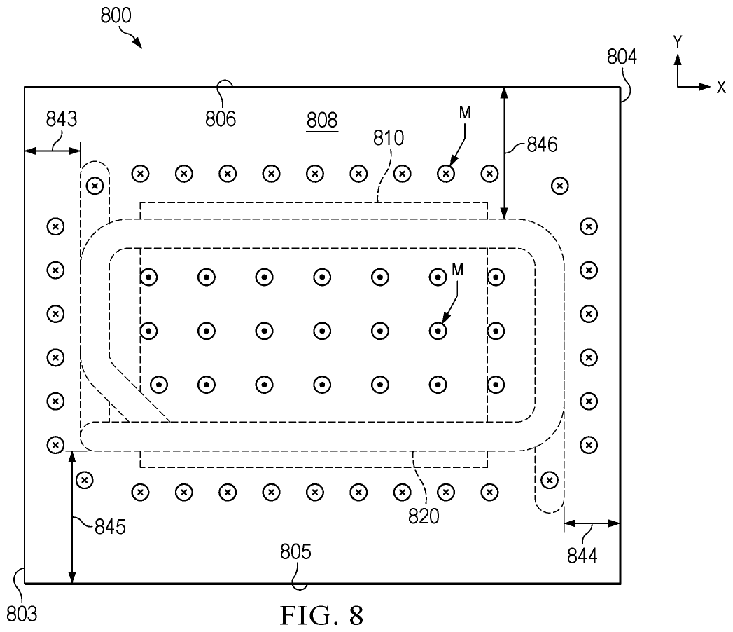

FIG. 8 shows another leadframeless electronic apparatus example 800 with a packaged electronic device 810 and a coil 820 in a molded magnetic structure 808 with terminals of the packaged electronic device 810 and of the coil 820 exposed along a bottom side of the apparatus 800. In this example, the coil 820 includes one or more turns that at least partially encircle an axis that extends along the third direction Z (e.g., out of the page in the top view of FIG. 8). The apparatus 800 in this example includes sides 803-806 and spacing distances 843-846 generally similar to the sides 103-106 and spacing distances 143-146 described above in connection with FIGS. 1-1B, and the packaged electronic device 810 can be the same as the electronic device 110 described above, although not a requirement of all possible implementations. The different configuration of the turns of the coil 820 in the example of FIG. 8 provides different magnetic field lines (e.g., labeled M in FIG. 8). In addition to the illustrated spacing distances 843-846 in FIG. 8, certain implementations also include nonzero spacing (e.g., along a third direction in an out of the page in the orientation of FIG. 8) between the top side of the packaged electronic device 810 and the lower extent of the coil 820, as well as non-zero spacing between the uppermost extent of the top turn of the coil 120 and the top side of the molded magnetic structure 808, for example, to provide a magnetic flux path for the desired operation of the coil 820 in a host circuit or system. Other coil configurations and/or orientations are possible, where the examples of FIGS. 1 and 8 are nonlimiting examples.

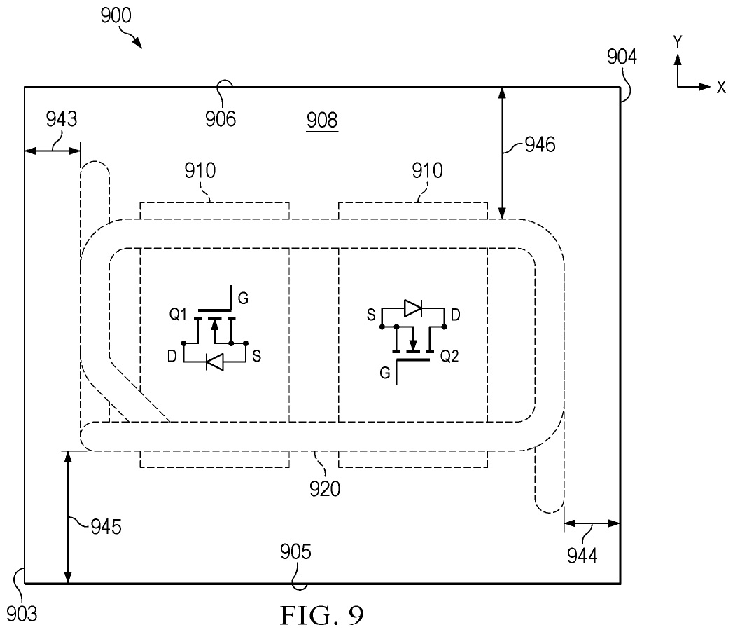

FIG. 9 shows a partial top view of a further leadframeless electronic apparatus example 900 with two transistor packaged electronic devices 910 and a coil 920 in a magnetic molded structure 908 with exposed terminals. The apparatus 900 in this example includes sides 903-906 and spacing distances 943-946 generally similar to the sides 103-106 and spacing distances 143-146 described above in connection with FIGS. 1-1B, and the coil 920 in one example is substantially the same as the coil 820 described above in connection with FIG. 8, although not a requirement of all possible implementations and other coil forms and orientations (e.g., FIGS. 1-1B above) can be used in other implementations. As schematically illustrated in the example of FIG. 9, the individual packaged electronic devices 910 each include a corresponding n-channel FET transistor with the first instance of the packaged electronic device 910 including the first transistor Q1 and the second instance including the second transistor Q2 illustrated in the system schematic of FIG. 1C above. In this example, the apparatus 900 facilitates use of SOT or other single transistor packaged electronic devices 910 integrated with a coil 922 form the core of a DC to DC converter or other half bridge based power conversion circuit (e.g., single phase DC to AC half bridge inverter module), with a host circuit board (not shown) providing suitable interconnections between the transistors Q1 and Q2 and the coil 920 in order to provide a power conversion system. As with the above examples, the implementation of FIG. 9 facilitates small system form factor and high power density in power conversion and other system applications by integrating the coil 920 with one or more packaged electronic devices 910 in an integrated electronic apparatus 900 with portions of the coil 920 and the packaged electronic devices 910 enclosed by the molded magnetic structure 908 and terminals of the coil 920 and the packaged electronic devices 910 being exposed outside the molded magnetic structure 908 in a manner similar to that illustrated above in FIG. 1 for soldering to a system circuit board or installation into a system socket (not shown).

Modifications are possible in the described examples, and other implementations are possible, within the scope of the claims.

What is claimed is:

1. An apparatus, comprising:
a packaged electronic device having a first terminal;
a coil having a second terminal that is spaced apart from the first terminal; and
a magnetic structure that encloses portions of the packaged electronic device and the coil and exposes respective portions of the first and second terminals.

2. The apparatus of claim 1, wherein the packaged electronic device includes a semiconductor die electrically connected to the first terminal, and a non-magnetic structure that encloses the semiconductor die and exposes the portion of the first terminal.

3. The apparatus of claim 2, wherein the semiconductor die includes a transistor with a transistor terminal that is electrically connected to the first terminal.

4. The apparatus of claim 1, wherein the coil is spaced apart from the packaged electronic device.

5. The apparatus of claim 4, wherein:
the apparatus has opposite first and second sides, opposite third and fourth sides, and opposite fifth and sixth sides;
the third and fourth sides are spaced apart from one another along a first direction;
the fifth and sixth sides are spaced apart from one another along a second direction that is orthogonal to the first direction;
the first and second sides are spaced apart from one another along a third direction that is orthogonal to the first and second directions;
the magnetic structure exposes the respective portions of the first and second terminals along the first side of the apparatus;
the coil is spaced apart from the packaged electronic device along the third direction; and
the coil is spaced apart from the second side of the apparatus along the third direction.

6. The apparatus of claim 5, wherein the coil is spaced apart from the third, fourth, fifth, and sixth sides.

7. The apparatus of claim 5, wherein the coil includes a turn that at least partially encircles an axis that lies in a plane of the first and second directions.

8. The apparatus of claim 5, wherein the coil includes a turn that at least partially encircles an axis that extends along the third direction.

9. The apparatus of claim 1, wherein the packaged electronic device has one of a flat no-lead and a small outline transistor package shape.

10. A system, comprising:
a circuit board having a conductive trace;
an apparatus attached to the circuit board and comprising: a packaged electronic device having a first terminal electrically connected to the conductive trace; a coil having a second terminal that is spaced apart from the first terminal and electrically connected to the conductive trace; and a magnetic structure that encloses portions of the packaged electronic device and the coil and exposes respective portions of the first and second terminals.

11. The system of claim 10, wherein the packaged electronic device includes a semiconductor die electrically connected to the first terminal, and a non-magnetic structure that encloses the semiconductor die and exposes the portion of the first terminal.

12. The system of claim 10, wherein the coil is spaced apart from the packaged electronic device.

13. The system of claim 12, wherein:
the apparatus has opposite first and second sides, opposite third and fourth sides, and opposite fifth and sixth sides;
the third and fourth sides are spaced apart from one another along a first direction;
the fifth and sixth sides are spaced apart from one another along a second direction that is orthogonal to the first direction;
the first and second sides are spaced apart from one another along a third direction that is orthogonal to the first and second directions;
the magnetic structure exposes the respective portions of the first and second terminals along the first side of the apparatus;
the coil is spaced apart from the packaged electronic device along the third direction; and
the coil is spaced apart from the second side of the apparatus along the third direction.

14. The system of claim 13, wherein the coil is spaced apart from the third, fourth, fifth, and sixth sides.

15. The system of claim 10, wherein the packaged electronic device has one of a flat no-lead and a small outline transistor package shape.

16. A method of manufacturing an electronic apparatus, the method comprising:
attaching a first terminal of a packaged electronic device to a carrier;
attaching a second terminal of a coil to the carrier;
performing a molding process using a molding compound to form a molded structure that encloses portions of the packaged electronic device and the coil; and
removing the carrier to expose portions of the first and second terminals.

17. The method of claim 16, wherein the molding compound is a magnetic molding compound.

18. The method of claim 16, wherein the carrier is a tape.

19. The method of claim 16, wherein the carrier is a lead frame or a substrate.

20. The method of claim 19, wherein removing the carrier includes performing a grinding process to remove the lead frame or substrate to expose the respective portions of the first and second terminals.
